(19) United States
(12) Patent Application Publication
(10) Pub. No.: US 2022/0300681 A1
(43) Pub. Date: Sep. 22, 2022

(54) DEVICES, SYSTEMS, METHODS, AND MEDIA FOR POINT CLOUD DATA AUGMENTATION USING MODEL INJECTION

(71) Applicants: Yuan REN, Thornhill (CA); Ehsan TAGHAVI, Markham (CA); Bingbing LIU, Markham (CA)

(72) Inventors: Yuan REN, Thornhill (CA); Ehsan TAGHAVI, Markham (CA); Bingbing LIU, Markham (CA)

(21) Appl. No.: 17/203,718

(22) Filed: Mar. 16, 2021

(51) Int. Cl. G06F 30/27; G06T 7/50

(52) U.S. Cl. CPC G06F 30/27; G06T 7/50; G06T 2207/10028

(57) ABSTRACT

Devices, systems, methods, and media are described for point cloud data augmentation using model injection, for the purpose of training machine learning models to perform point cloud segmentation and object detection. A library of surface models is generated from point cloud object instances in LIDAR-generated point cloud frames. The surface models can be used to inject new object instances into target point cloud frames at an arbitrary location within the target frame to generate new, augmented point cloud data. The augmented point cloud data may then be used as training data to improve the accuracy of a machine learned model trained using a machine learning algorithm to perform a segmentation and/or object detection task.

### RELATED APPLICATION DATA

This is the first patent application related to this matter.

### FIELD

The present application generally relates to point cloud data augmentation for machine learning, and in particular to devices, systems, methods, and media for point cloud data augmentation using model injection.

### BACKGROUND

A Light Detection And Ranging (LiDAR, also referred to a “Lidar” or “LIDAR” herein) sensor generates point cloud data representing a three-dimensional (3D) environment (also called a “scene”) scanned by the LIDAR sensor. A single scanning pass of the LIDAR sensor generates a “frame” of point cloud data (referred to hereinafter as a “point cloud frame”), consisting of a set of points from which light is reflected from one or more points in space, within a time period representing the time it takes the LIDAR sensor to perform one scanning pass. Some LIDAR sensors, such as spinning scanning LIDAR sensors, includes a laser array that emits light in an arc and the LIDAR sensor rotates around a single location to generate a point cloud frame; others LIDAR sensors, such as solid-state LIDAR sensors, include a laser array that emits light from one or more locations and integrate reflected light detected from each location together to form a point cloud frame. Each laser in the laser array is used to generate multiple points per scanning pass, and each point in a point cloud frame corresponds to an object reflecting light emitted by a laser at a point in space in the environment. Each point is typically stored as a set of spatial coordinates (X, Y, Z) as well as other data indicating values such as intensity (i.e. the degree of reflectivity of the object reflecting the laser). The other data may be represented as an array of values in some implementations. In a scanning spinning LIDAR sensor, the Z axis of the point cloud frame is typically defined by the axis of rotation of the LIDAR sensor, roughly orthogonal to an azimuth direction of each laser in most cases (although some LIDAR sensor may angle some of the lasers slightly up or down relative to the plane orthogonal to the axis of rotation).

Point cloud data frames may also be generated by other scanning technologies, such as high-definition radar or depth cameras, and theoretically any technology using scanning beams of energy, such as electromagnetic or sonic energy, could be used to generate point cloud frames. Whereas examples will be described herein with reference to LIDAR sensors, it will be appreciated that other sensor technologies which generate point cloud frames could be used in some embodiments.

A LIDAR sensor is one of the primary sensors used in autonomous vehicles to sense an environment (i.e. scene) surrounding the autonomous vehicle. An autonomous vehicle generally includes an automated driving system (ADS) or advanced driver-assistance system (ADAS). The ADS or the ADAS includes a perception submodule that processes point cloud frames to generate predictions which are usable by other sub systems of the ADS or ADAS for localization of the autonomous vehicle, path planning for the autonomous vehicle, motion planning for the autonomous vehicle, or trajectory generation for the autonomous vehicle.

However, because of the sparse and unordered nature of point cloud frames, the cost of collecting and labeling point cloud frames at the point level is time consuming and expensive. Points in a point cloud frame must be clustered, segmented, or grouped (e.g., using object detection, semantic segmentation, instance segmentation, or panoptic segmentation) such that a collection of points in the point cloud frame may be labeled with an object class (e.g., “pedestrian” or “motorcycle”) or an instance of an object class (e.g. “pedestrian #3”), with these labels being used in machine learning to train models for prediction tasks on point cloud frames, such as object detection or various types of segmentation. This cumbersome process of labeling has resulted in limited availability of labeled point cloud frames representing various road and traffic scenes, which are needed to train high accuracy models for prediction tasks on point cloud frames using machine learning.

Examples of such labeled point cloud datasets that include point cloud frames that are used to train models using machine learning for prediction tasks, such as segmentation and objection detection, are the SemanticKITTI dataset (described by J. Behley et al., “SemanticKITTI: A Dataset for Semantic Scene Understanding of LiDAR Sequences,” 2019 IEEE/CVF International Conference on Computer Vision (ICCV), Seoul, Korea (South), 2019, pp. 9296-9306, doi: 10.1109/ICCV.2019.00939), KITTI360 (described by J. Xie, M. Kiefel, M. Sun and A. Geiger, “Semantic Instance Annotation of Street Scenes by 3D to 2D Label Transfer,” 2016 IEEE Conference on Computer Vision and Pattern Recognition (CVPR), Las Vegas, Nev., USA, 2016, pp. 3688-3697, doi: 10.1109/CVPR.2016.401.), and Nuscenes-lidarseg (described by H. Caesar et al., “nuScenes: A Multimodal Dataset for Autonomous Driving,” 2020 IEEE/CVF Conference on Computer Vision and Pattern Recognition (CVPR), Seattle, Wash., USA, 2020, pp. 11618-11628, doi: 10.1109/CVPR42600.2020.01164.), which may be the only available point cloud datasets with semantic information, i.e. point cloud frames labeled with semantic information for training models for prediction tasks on point cloud frames, such as segmentation or object detection.

However, these available point cloud datasets generally do not include enough point cloud frames that include objects from certain object classes, and the set of point cloud frames that do include such objects exhibit a lack of diversity of instances of objects (“object instances”) within each such object class. Object classes appearing in limited numbers in the point cloud datasets may be referred to herein as disadvantaged classes. Disadvantaged classes in existing point cloud datasets are typically small and less common types of objects, such as pedestrians, bicycles, bicyclists, motorcycles, motorcyclists, trucks and other types of vehicles.

Disadvantaged classes may cause either or both of two problems. The first problem arises from a lack of environmental or contextual diversity. If object instances of a disadvantaged class appear in only a few point cloud frames in the point cloud dataset, the model (e.g. deep neural network model) trained for a prediction task on point cloud frames (such as object detection or various types of segmentation) may not learn to recognize an object instance of the disadvantaged class (i.e. a cluster of points corresponding to an object of the disadvantaged class) when the object instance appears in environments that differ from the point cloud frames in which object instances of the disadvantaged class appears in the point cloud dataset. For example, if the point cloud frames in the point cloud dataset only include object instances of a “motorcyclist” (i.e. a disadvantaged class “motorcyclist”) in point cloud frames corresponding to parking lots, the model may not be able to identify a motorcyclist in a road environment. The second problem arises from a lack of object instance diversity. If object instances of a disadvantaged class appears in very small numbers in the point cloud dataset, the diversity of the object instances themselves cannot be guaranteed. For example, if the point cloud frames in the point cloud dataset only include object instances of a “motorcyclist” (i.e. a disadvantaged class “motorcyclist”) riding a sport bike, the model may not be able to identify a motorcyclist who rides a scooter.

Traditionally, the problem of using sparse point cloud datasets with disadvantaged classes for training a model for a prediction task on point cloud frames, such as segmentation and object detection, has been addressed through data augmentation. Data augmentation may be regarded as a process for generating new training samples (e.g., new semantically labeled point cloud frames) from an already existing labeled point cloud dataset using any technique that can assist in improving the training of a model for a prediction task on point cloud frames to achieve higher model accuracy (i.e. a model that generates better predictions). The environmental diversity problem identified above is typically addressed by a method that involves extracting an object from one point cloud frame and injecting the extracted object into other point cloud frame to generate additional point cloud frames containing an object instance of the disadvantaged class, which can be used to further train the model. The point cloud frame into which the object instance is injected may correspond to a different environment, and so may assist the model in learning to recognize object instances of the disadvantaged class in other environments. Example of such techniques include Yan Yan, Yuxing Mao, Bo Li, “SECOND: Sparsely Embedded Convolutional Detection”, Sensors 2018, 18(10), 3337; https://doi.org/10.3390/s18103337; Alex H. Lang, Sourabh Vora, Holger Caesar, Lubing Zhou, Jiong Yang, Oscar Beijbom, “PointPillars: Fast Encoders for Object Detection from Point Clouds”, https://arxiv.org/abs/1812.05784; and Yin Zhou, Oncel Tuzel, “VoxelNet: End-to-End Learning for Point Cloud Based 3D Object Detection”, https://arxiv.org/abs/1711.06396. These existing approaches to data augmentation typically proceed in the following fashion: first, a database of object instances is generated by extracting clusters (i.e. point clouds of objects) from point cloud frames annotated with bounding boxes around the object instances. Second, the object instances are randomly chosen from the database and the chosen object instances are injected into a similar position in other point cloud frames. Finally, a collision test is implemented to avoid object position confliction (e.g., overlap in space with another object within the target point cloud frame into which the object instance is injected). The object instances extracted from a point cloud frame are usually half-side, due to the directional nature of the LiDAR sensor. Therefore, during injection of the object instance, the original position and pose of the object instance cannot be changed significantly, in order to avoid the side of the object instance without points defining its surface facing the LIDAR sensor. These existing approaches may increase the number of object instances of disadvantaged classes per point cloud frame and simulate an object instance existing in different environments.

However, these existing approaches to solving the environmental diversity problem typically have three limitations. First, they cannot generate reasonable scanlines on the surface of an injected object instance, and they also cannot generate a realistic object shadow (i.e. occlusion of other object in the scene located behind the injected object instance). Second, the position and pose of the injected object instance are necessarily identical or nearly identical in the two point cloud frames (i.e. the original point cloud frame where the object instance appears and the target point cloud frame into which the object instance is injected). Third, these existing approaches neglect the context in which object instances appear in different environments. For example, a person usually appears on sidewalk, but this context is not taken into account in the existing approaches to addressing environmental diversity. Furthermore, because the object instance must typically appear in the same orientation and location relative to the LIDAR sensor, these approaches do not permit an object instance to be injected into a target point cloud frame in a location or orientation which would make the most sense in context; for example, if the target point cloud frame consists entirely of sidewalks and buildings except for a small parking lot extending only 20 meters away from the LIDAR sensor, and the object instance being injected is a truck located 50 meters away from the LIDAR sensor in the original point cloud frame, the object instance cannot be injected into the target point cloud frame in a location that would make sense in context.

The object instance diversity problem has typically been addressed using two different approaches. The first approach involves positioning computer assisted design (CAD) models of objects into spatial locations within point cloud frames, and then generating the points to represent each object by using the CAD model of an object and LIDAR parameters (e.g., the mounting pose of the LIDAR sensor and the pitch angle of each beam of light emitted by a laser of the LIDAR sensor) of the target point cloud frame. Examples of the first approach include Jin Fang , Feilong Yan, Tongtong Zhao, Feihu Zhang, “Simulating LIDAR Point Cloud for Autonomous Driving using Real-world Scenes and Traffic Flows”; and Sivabalan Manivasagam, Shenlong Wang, Kelvin Wong, Wenyuan Zeng, Mikita Sazanovich, Shuhan Tan, Bin Yang, Wei-Chiu Ma, Raquel Urtasun, “LiDARsim: Realistic LiDAR Simulation by Leveraging the Real World”.

The examples of the first approach may enable CAD models of objects to be rotated and translated without any limitation, and to generate reasonable scanlines and shadows. Without the constraints of position and pose, context can be considered during injection, in contrast to the object instance injection approaches described above for addressing environmental diversity. However, CAD model based approaches typically have three limitations. First, CAD models are usually obtained from LiDAR simulators, such as GTAV (as described in Xiangyu Yue, Bichen Wu, Sanjit A. Seshia, Kurt Keutzer, Alberto L. Sangiovanni-Vincentelli, A LiDAR Point Cloud Generator: from a Virtual World to Autonomous Driving, arXiv:1804.00103) or CARLA (as described in Alexey Dosovitskiy, German Ros, Felipe Codevilla, Antonio Lopez, Vladlen Koltun, CARLA: An Open Urban Driving Simulator, arXiv:1711.03938), or they are purchased from 3D model websites. The diversity of the CAD models of objects available from these sources is typically very limited. Second, the style of the available CAD models of an object may differ from the real object to which they supposedly correspond. For example, if CAD models of Europa trucks are injected into point cloud frames corresponding to North American road environments, they may look very realistic despite the fact that no trucks with that style actually exist in the environments that the CAD model of the object is being trained to recognize and navigate. Third, CAD models of objects cannot provide accurate intensity values for injected object instances. The intensity of a point on the surface of an object is a function of the angle between the beam of light emitted by a laser and the surface that reflects the beam of light, as well as the reflectivity of the material that reflects the beam of light. However, most available CAD models of objects do not provide any information regarding the reflectivity of the surface materials of the model.

A second approach to addressing the object instance diversity problem is outlined by Waymo™ at https://blog.waymo.com/2020/04/using-automated-data -augmentation-to.html. Instead of using CAD models of objects to inject new object instances into point cloud frames, dense, complete point cloud scans of objects are used to inject new object instances into target point cloud frames. The advantages of dense, complete point cloud scans of objects are similar to those of CAD model of an object: they can be rotated and translated without any limitation during their injection, and they can also generate reasonable scanlines and shadows. The diversity of the injected point cloud scans of objects may be increased using eight different data augmentation methods: ground truth augmentation (i.e. adding two or more object instances of the same object together), random flip (i.e. flipping an object instance, e.g. horizontally), world scaling (i.e. scaling the size of the object instance), global translate noise (i.e. translating an object instance to a different location), frustum dropout (i.e. deleting a region of the visible surface of an object instance, e.g. to simulate partial occlusion), frustum noise (i.e. randomly perturbing the location of points of the object instance, e.g. to simulate slightly different surface details), random rotation (i.e. rotation of the object instance about an axis), and random drop points (i.e. deleting a randomly selected subset of points of the object instance, e.g. to simulate a lower-resolution scan).

However, the use of dense point cloud object scans to inject new object instances into target point cloud frames also has a number of limitations. First, dense, complete point cloud scans of objects are needed to implement this approach. In contrast, the object instances in point cloud frames generated by a LIDAR are usually sparse and half-side. Thus, a large dataset of carefully, densely, and completely scanned objects would needed to be assembled before this approach could be implemented. Second, object symmetry is often used to generate complete point cloud scans of objects based on half-side scans. However, many small objects encountered in road environments or other environments, such as pedestrians, motorcyclists, and bicyclists, are not symmetrical. Therefore, the need to assemble a large database of point cloud scans of objects cannot be addressed simply by relying on symmetry to extrapolate from an existing point cloud dataset that includes point cloud frames with dense half-scans of objects. Third, the intensity of dense point cloud scans of objects may not be accurate because the dense point cloud scans of objects are usually captured from different points of view in order to capture a complete point cloud scan of an object. For example, a 3D scanner may be rotated around an object in at least one direction in order to generate a complete, dense scan of an object; this results in scans of the same point from multiple directions, thereby generating conflicting intensity readings for that point, and generating intensity readings for different points that are relative to different scan directions and are therefore not consistent with each other.

There thus exists a need for data augmentation techniques for point cloud datasets that overcome one or more of the limitations of existing approaches described above.

### SUMMARY

The present disclosure describes devices, systems, methods, and media for point cloud data augmentation using model injection, for the purpose of training machine learning models for a prediction task on point cloud frames, such as segmentation or object detection. Examples devices, systems, methods, and media described herein may generate a library of surface models, which can be used to inject new point cloud object instances into a target point cloud frame at an arbitrary location within the target point cloud frame to generate a new, augmented point cloud frame. The augmented point cloud frame may then be used as training data to improve the accuracy of the trained machine learned model for the prediction task on point cloud frames (i.e. a machine learned model trained using a machine learning algorithm and the original point cloud dataset).

In the present disclosure, the term “LIDAR” (also “LiDAR” or “Lidar”) refers to Light Detection And Ranging, a sensing technique in which a sensor emits laser beams and collects the location, and potentially other features, from light-reflective objects in the surrounding environment.

In the present disclosure, the term “point cloud object instance”, or simply “object instance” or “instance”, refers to a point cloud for a single definable object such, as a car, house, or pedestrian, that can be defined as a single object. For example, typically a road cannot be an object instance; instead, a road may be defined within a point cloud frame as defining a scene type or region of the frame.

In the present disclosure, the term “injection” refers to the process of adding a point cloud object instance to a point cloud frame. The term “frame” refers to a point cloud frame unless otherwise indicated; an “original” frame is a frame containing a labelled point cloud object instance which may be extracted for injection into a “target” frame; one the object instance has been injected into the target frame, the target frame may be referred to as an “augmented” frame, and any dataset of point cloud data to which augmented frames have been added may be referred to as “augmented point cloud data” or simply “augmented data”. The terms “annotated” and “labelled” are used interchangeably to indicate association of semantic data with point cloud data, such as scene type labels attached to point cloud frames or regions thereof, or object class labels attached to object instances within a point cloud frame.

In the present disclosure, a “complete point cloud object scan” refers to a point cloud corresponding to an object scanned from more than one location such that multiple surfaces of the object are represented in the point cloud. A “dense” point cloud refers to a point cloud corresponding to one or more surfaces of an object in which the number of points per area unit of the surface is relatively high. A “surface model” refers to a three-dimensional model of one or more surfaces of an object; the surface(s) may be represented as polygons, points, texture maps, and/or any other means of representing three-dimensional surfaces.

Examples devices, systems, methods, and media described herein may enrich disadvantaged classes in an original point cloud dataset (i.e. a dataset of labeled point cloud frames). The surface models are derived from point cloud frames with point-level labels (e.g., semantically segmented point cloud frames). The object instances labeled with semantic labels in the original point cloud frames may be incomplete (half-side) and sparse. However, methods and systems described herein may derive dense, half-side point cloud object instances from the incomplete, sparse object instances in the original point cloud frames. These dense point cloud object instances may be used as surface models for injecting new point cloud object instances into target frames.

Example devices, systems, methods, and media described herein inject point cloud object instances derived from actual point cloud frames generated by a LIDAR sensor, rather than using CAD models of objects or complete dense point cloud scans of objects to inject new point cloud objects instances into a target point cloud frame as in existing approaches that attempt to address the object instance diversity problem; however, the described methods and systems can also be leveraged to inject point cloud object instances using a CAD model of an object or a dense, complete point cloud object scan . The injected point cloud object instances can be obtained from the point cloud frames received from different types of LIDAR sensors used to generate the target point cloud frame (e.g., the range and scan line configurations of the laser array of the LIDAR sensor used to generate the original point cloud frame and target point cloud frame need not be the same). The injected point cloud object instances generated using examples methods and systems described herein have reasonable scan lines (e.g., realistic direction, density, and intensity) on their surface, as well as realistic shadows. In general, the augmented point cloud frames generated using the examples methods and system described herein may be very similar to real point cloud frames generated by a LIDAR sensor.

Example methods and system described herein may be configured to use context to further improve the realism and usefulness of the generated augmented point cloud frames. The object class, quantity, position, and distribution of the injected point cloud object instances may be fully controlled using parameters: for example, if the example methods and systems describe herein are instructed to inject five persons into a target point cloud frame, the five point cloud object instances may be injected with a distribution wherein each point cloud object instance has a 90% chance of being located on a sidewalk, and a 10% chance of being located on a road.

Example methods and systems described herein may perform the following sequence of operations to augment point cloud data frames or a point cloud dataset. First, a library of surface models is generated by processing the point cloud dataset including existing point cloud frames generated by a LIDAR sensor and annotated with point-level labels. The library generation process may involve object extraction and clustering to extract object instances from the original point cloud frames, followed by point cloud up-sampling on the azimuth-elevation plane to derive high-density point cloud object instances from the extracted point cloud object instances. Second, point cloud object instances selected from the library are injected into target point cloud frames to generate augmented point cloud frames. The injection process may involve anchor point selection to determine a location within the target point cloud frame where the point cloud object instance may be injected, object injection to situate the surface model in the target point cloud frame, and scanline and shadow generation to down-sample the surface model to simulate scanlines of the LIDAR sensor at the anchor location in the target point cloud frame and to generate shadows occluding other point cloud objects within the target point cloud frame.

Some examples of the method and systems described herein may exhibit advantages over existing approaches. The library of surface models can be obtained directly from labeled point cloud frames, but may also be populated using CAD models of objects and dense point cloud object scans and still take advantage of the injection techniques described herein. The surface models and target point cloud frames can be obtained from point cloud frames generated by different types of LIDAR sensors: for example, a point cloud object instance extracted from a point cloud frame generated by a 32-beam LiDAR sensor may be inserted into a target point cloud frame generated by a 64-beam LIDAR sensor. The scan line characteristics (including density, direction, and intensity) of the injected point cloud object instances and the shadows thrown by the injected point cloud object instances are realistically simulated. The type, quantity and injection location (i.e. anchor position) of the injected point cloud object instances can be controlled by parameters. Labeling time (i.e. time for labeling the points of point cloud frames) may be substantially reduced, because only the objects of interest in the original point cloud frames need to be labeled before they are used to populate the library of high-density point cloud object instances and injected into target point cloud frames; it may not be necessary to label all points in the original point cloud frames.

In some aspects, the present disclosure describes a method. A point cloud object instance is obtained. The point cloud object instance is up-sampled using interpolation to generate a surface model.

In some aspects, the present disclosure describes a system for augmenting point cloud data. The system comprises a processor device, and a memory. The memory stores a point cloud object instance, a target point cloud frame, and machine-executable instructions. The machine-executable instructions, when executed by the processor device, cause the system to perform a number of operations. The point cloud object instance is up-sampled using interpolation to generate a surface model. An anchor location is determined within the target point cloud frame. The surface model is transformed based on the anchor location to generate a transformed surface model. Scan lines of the transformed surface model are generated, each scan line comprising a plurality of points aligned with scan lines of the target point cloud frame. The scan lines of the transformed surface model are added to the target point cloud frame to generate an augmented point cloud frame.

In some examples, the point cloud object instance comprises orientation information indicating an orientation of the point cloud object instance in relation to a sensor location. The point cloud object instance further comprises, for each of a plurality of points in the point cloud object instance, point intensity information, and point location information. The surface model comprises the orientation information, point intensity information, and point location information of the point cloud object instance.

In some examples, the point cloud object instance comprises a plurality of scan lines, each scan line comprising a subset of the plurality of points. Up-sampling the point cloud object instance comprises adding points along at least one scan line using linear interpolation.

In some examples, up-sampling the point cloud object instance further comprises adding points between at least one pair of scan lines of the plurality of scan lines using linear interpolation.

In some examples, adding a point using linear interpolation comprises assigning point location information to the added point based on linear interpolation of the point location information of two existing points, and assigning point intensity information to the added point based on linear interpolation of the point intensity information of the two existing points.

In some aspects, the present disclosure describes a method. A target point cloud frame is obtained. An anchor location within the target point cloud frame is determined. A surface model of an object is obtained. The surface model is transformed based on the anchor location to generate a transformed surface model. Scan lines of the transformed surface model are generated, each scan line comprising a plurality of points aligned with scan lines of the target point cloud frame. The scan lines of the transformed surface model are added to the target point cloud frame to generate an augmented point cloud frame.

In some examples, the surface model comprises a dense point cloud object instance.

In some examples, obtaining the surface model comprises obtaining a point cloud object instance, and up-sampling the point cloud object instance using interpolation to generate the surface model.

In some examples, the surface model comprises a computer assisted design (CAD) model.

In some examples, the surface model comprises a complete dense point cloud object scan.

In some examples, the method further comprises determining shadows of the transformed surface model, identifying one or more occluded points of the target point cloud frame located within the shadows, and removing the occluded points from the augmented point cloud frame.

In some examples, generating the scan lines of the transformed surface model comprises generating a range image, comprising a two-dimensional pixel array wherein each pixel corresponds to a point of the target point cloud frame, projecting the transformed surface model onto the range image, and for each pixel of the range image, in response to determining that the pixel contains at least one point of the projection of the transformed surface model, identifying a closest point of the projection of the transformed surface model to the center of the pixel and adding the closest point to the scan line.

In some examples, the surface model comprises object class information indicating an object class of the surface model. The target point cloud frame comprises scene type information indicating a scene type of a region of the target point cloud frame. Determining the anchor location comprises, in response to determining that the surface model should be located within the region based on the scene type of the region and the object class of the surface model, positioning the anchor location within the region.

In some examples, transforming the surface model based on the anchor location comprises rotating the surface model about an axis defined by a sensor location of the target point cloud frame, while maintaining an orientation of the surface model in relation to the sensor location, between a surface model reference direction and an anchor point direction, and translating the surface model between a reference distance and an anchor point distance.

In some examples, the method further comprises using the augmented point cloud frame to train a machine learned model.

In some aspects, the present disclosure describes a non-transitory processor-readable medium having stored thereon a surface model generated by one or more of the methods described above.

In some aspects, the present disclosure describes a non-transitory processor-readable medium having stored thereon an augmented point cloud frame generated by one or more of the methods described above.

In some aspects, the present disclosure describes a non-transitory processor-readable medium having machine-executable instructions stored thereon which, when executed by a processor device of a device, cause the device to perform the steps of one or more of the methods described above.

### BRIEF DESCRIPTION OF THE DRAWINGS

Reference will now be made, by way of example, to the accompanying drawings which show example embodiments of the present application, and in which:

FIG. 1A is an upper front right side perspective view of an example simplified point cloud frame, providing an operating context for embodiments described herein;

FIG. 1B is an upper front right side perspective view of an example point cloud object instance labelled with a “bicyclist” object class, suitable for use by embodiments described herein;

FIG. 1C is an upper front right side perspective view of an example surface model based on the point cloud object instance of FIG. 1B, as generated by embodiments described herein;

FIG. 1D is top view of the point cloud object instance of FIG. 1B undergoing rotation, translation and scaling prior to injection into a target point cloud frame, in accordance with examples described herein;

FIG. 2 is a block diagram illustrating some components of an example system for generating surface models and augmented point cloud frames, in accordance with examples described herein;

FIG. 3 is a block diagram illustrating the operation of the library generation module, data augmentation module, and training module of FIG. 2;

FIG. 4 is a flowchart illustrating steps of an example method for generating a surface model that may be performed by the library generation module of FIG. 3;

FIG. 5 is a flowchart illustrating steps of an example method for generating an augmented point cloud frame that may be performed by the data augmentation module of FIG. 3; and

FIG. 6 is a flowchart illustrating steps of an example method for training a machine learned model using augmented point cloud data generated by the methods of FIG. 4 and FIG. 5.

Similar reference numerals may have been used in different figures to denote similar components.

### DESCRIPTION OF EXAMPLE EMBODIMENTS

The present disclosure describes example devices, systems, methods, and media for adaptive scene augmentation for training machine learning models to perform point cloud segmentation and/or object detection.

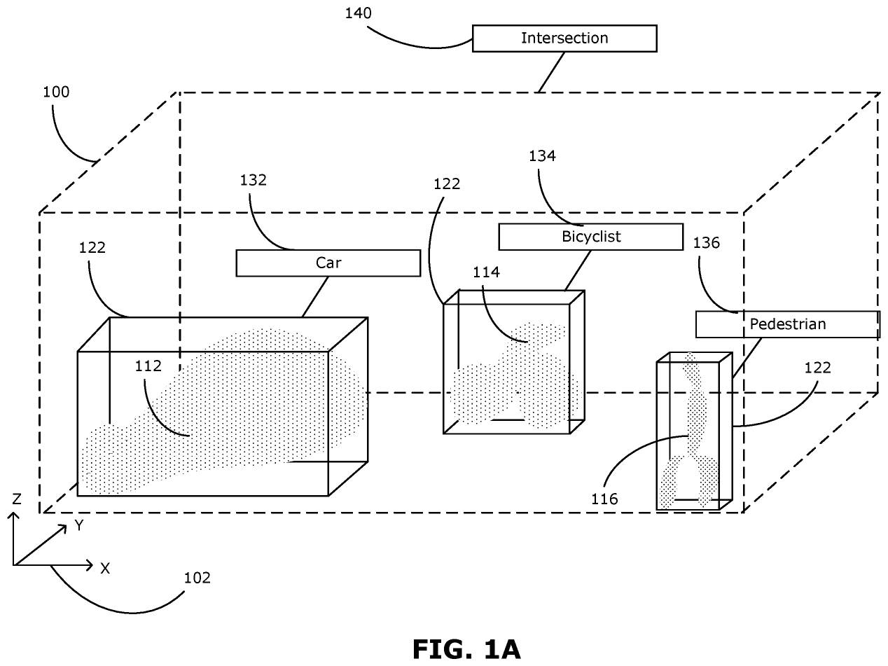

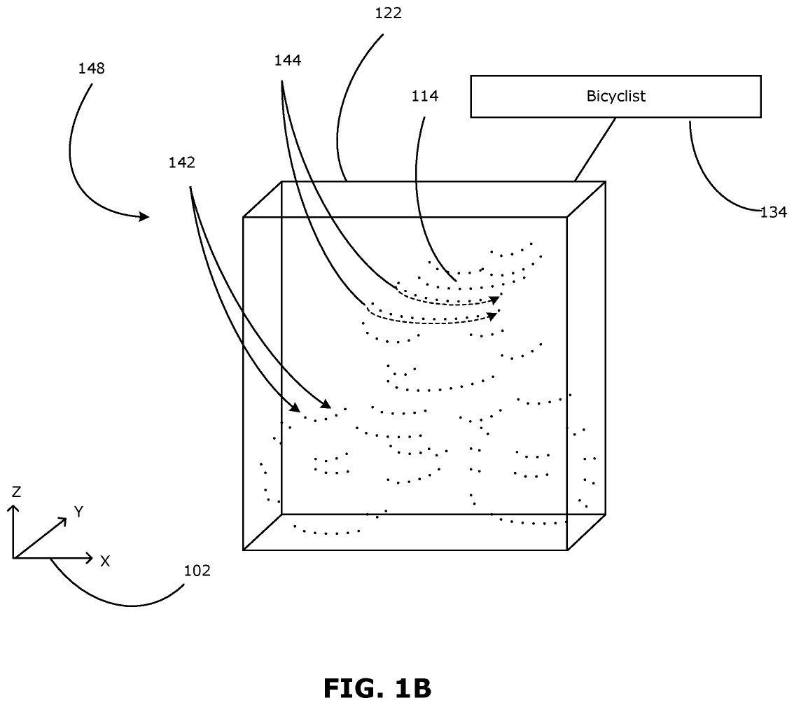

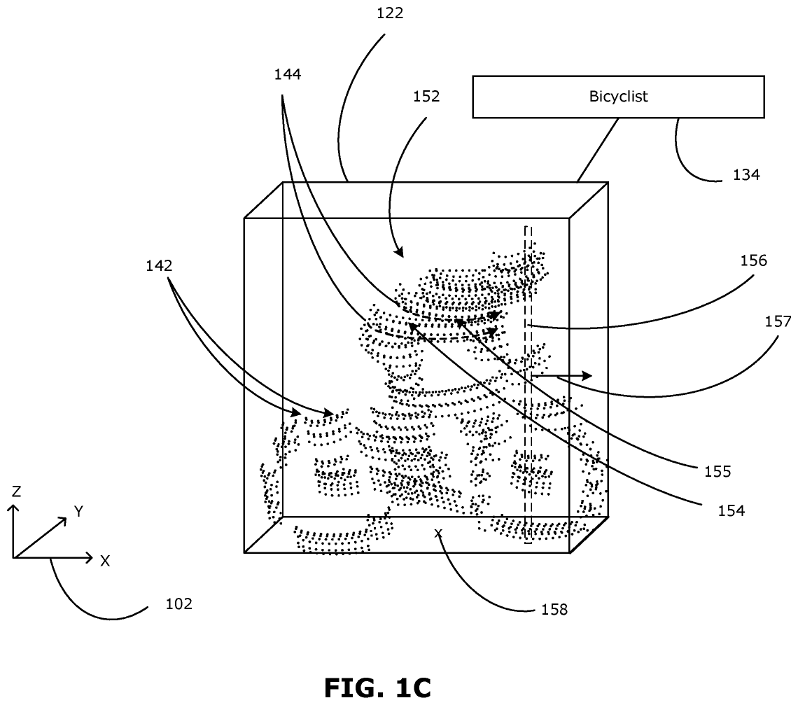

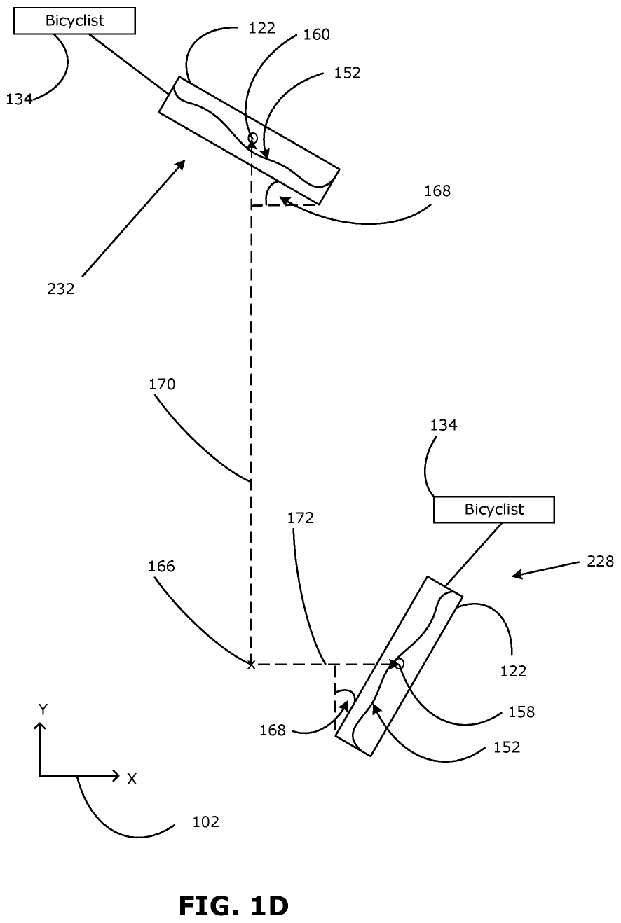

FIG. 1A shows an example simplified point cloud frame 100, with points mapped to a three-dimensional coordinate system 102 X, Y, and Z, wherein the Z dimension extends upward, typically as defined by the axis of rotation of the LIDAR sensor or other panoramic sensor generating the point cloud frame 100. The point cloud frame 100 includes a number of points, each of which may be represented by a set of coordinates (x, y, z) within the point cloud frame 100 along with a vector of other values, such as an intensity value indicating the reflectivity of the object corresponding to the point. Each point represents a reflection of light emitted by a laser at a point in space relative to the LIDAR sensor corresponding to the point coordinates. Whereas the example point cloud frame 100 is shown as a box-shape or rectangular prism, it will be appreciated that a typical point cloud frame captured by a panoramic LIDAR sensor is typically a 360 degree panoramic view of the environment surrounding the LIDAR sensor, extending out to a full detection range of the LIDAR sensor. The example point cloud frame 100 is thus more typical of a small portion of an actual LIDAR-generated point cloud frame, and is used for illustrative purposes.

The points of the point cloud frame 100 are clustered in space where light emitted by the lasers of the LIDAR sensor are reflected by objects in the environment, thereby resulting in clusters of points corresponding to the surface of the object visible to the LIDAR sensor. A first cluster of points 112 corresponds to reflections from a car. In the example point cloud frame 100, the first cluster of points 112 is enclosed by a bounding box 122 and associated with an object class label, in this case the label “car” 132. A second cluster of points 114 is enclosed by a bounding box 122 and associated with the object class label “bicyclist” 134, and a third cluster of points 116 is enclosed by a bounding box 122 and associated with the object class label “pedestrian” 136. Each point cluster 112, 114, 116 thus corresponds to an object instance: an instance of object class “car”, “bicyclist”, and “pedestrian” respectively. The entire point cloud frame 100 is associated with a scene type label 140 “intersection” indicating that the point cloud frame 100 as a whole corresponds to the environment near a road intersection (hence the presence of a car, a pedestrian, and a bicyclist in close proximity to each other).

In some examples, a single point cloud frame may include multiple scenes, each of which may be associated with a different scene type label 140. A single point cloud frame may therefore be segmented into multiple regions, each region being associated with its own scene type label 140. Example embodiments will be generally described herein with reference to a single point cloud frame being associated with only a single scene type; however, it will be appreciated that some embodiments may consider each region in a point cloud frame separately for point cloud object instance injection using the data augmentation methods and systems described herein.

Each bounding box 122 is sized and positioned, each object label 132, 134, 136 is associated with each point cluster, and the scene label is associated with the point cloud frame 100 using data labeling techniques known in the field of machine learning for generating labeled point cloud frames . As described above, these labeling techniques are generally very time-consuming and resource-intensive; the data augmentation techniques described herein may be used in some examples to augment the number of labeled point cloud object instances within a point cloud frame 100, thereby reducing the time and resources required to manually identify and label point cloud object instances in point cloud frames.

The labels and bounding boxes of the example point cloud frame 100 shown in FIG. 1A correspond to labels applied in the context of object detection, and the example point cloud frame could therefore be included in a point cloud dataset that is used to train a machine learned model for object detection on point cloud frames. However, methods and systems described herein are equally applicable not only to models for object detection on point cloud frames, but also models for segmentation on point cloud frames, including semantic segmentation, instance segmentation, or panoptic segmentation of point cloud frames.

FIGS. 1B-1D will be described below with reference to the operations of example methods and systems described herein.

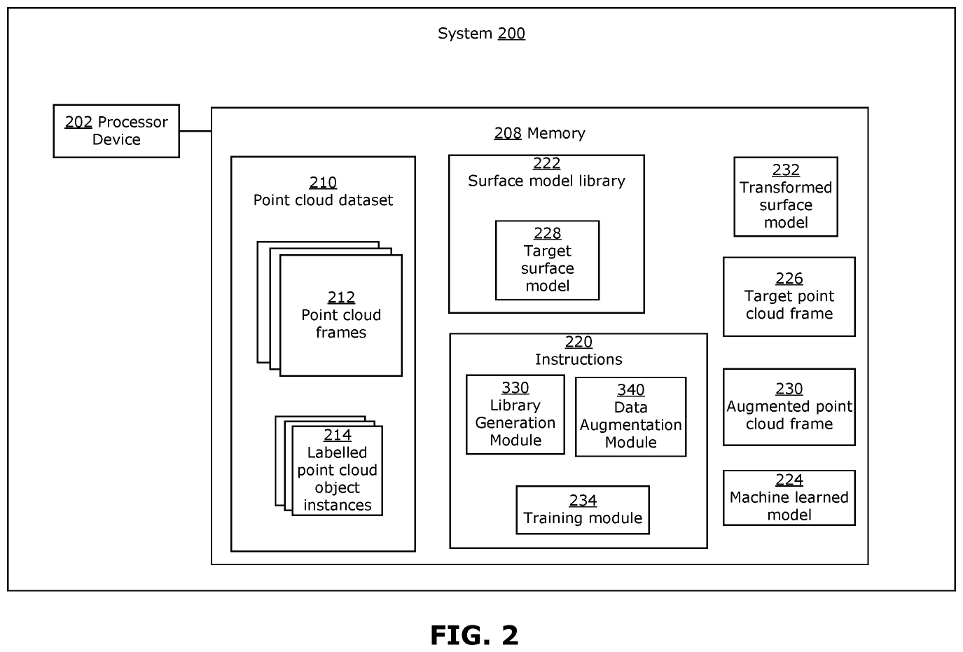

FIG. 2 is a block diagram of a computing system 200 (hereinafter referred to as system 200) for augmenting point cloud frames (or augmenting a point cloud dataset that includes point cloud frames). Although an example embodiment of the system 200 is shown and discussed below, other embodiments may be used to implement examples disclosed herein, which may include components different from those shown. Although FIG. 2 shows a single instance of each component of the system 200, there may be multiple instances of each component shown.

The system 200 includes one or more processors 202, such as a central processing unit, a microprocessor, an application-specific integrated circuit (ASIC), a field-programmable gate array (FPGA), a dedicated logic circuitry, a tensor processing unit, a neural processing unit, a dedicated artificial intelligence processing unit, or combinations thereof. The one or more processors 202 may collectively be referred to as a “processor device” or “processor 202”.

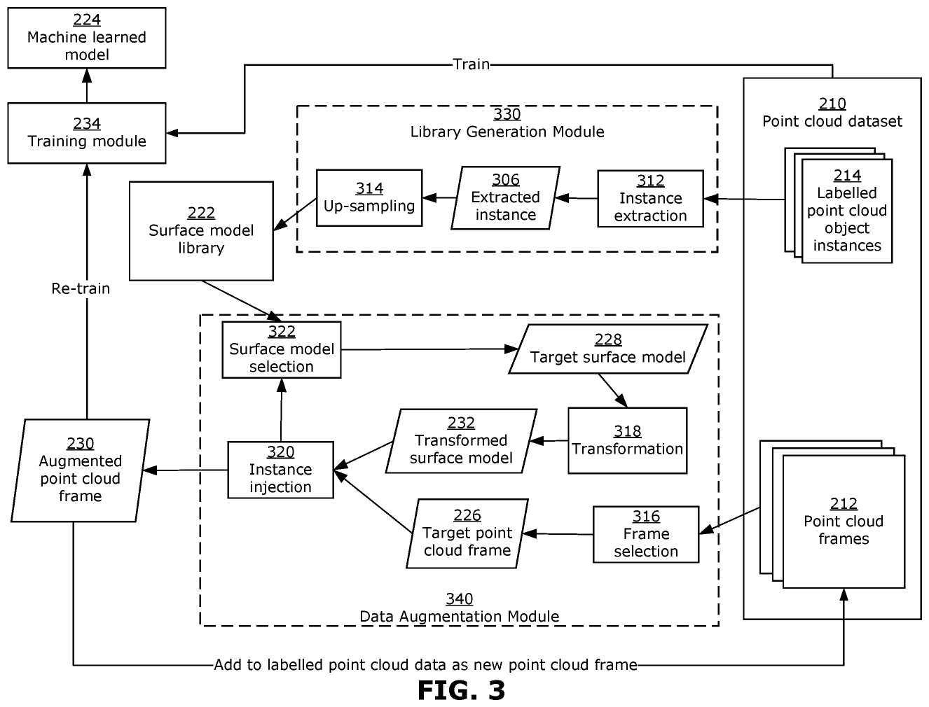

The system 200 includes one or more memories 208 (collectively referred to as “memory 208”), which may include a volatile or non-volatile memory (e.g., a flash memory, a random access memory (RAM), and/or a read-only memory (ROM)). The non-transitory memory 208 may store machine-executable instructions for execution by the processor 202, such as to carry out examples described in the present disclosure. A set of machine-executable instructions 220 defining a library generation module 330, a data augmentation module 340, and a training module 234 are shown stored in the memory 208, which may each be executed by the processor 202 to perform the steps of the methods described herein. The operation of the system 200 in executing the set of machine-executable instructions 220 defining the library generation module 330, a data augmentation module 340, and training module 234 is described below with reference to FIG. 3. The machine-executable instructions 220 defining the scene augmentation module 300 are executable by the processor 202 to perform the functions of each respective submodule thereof 312, 314, 316, 318, 320, 322. The memory 208 may include other machine-executable instructions, such as for implementing an operating system and other applications or functions.

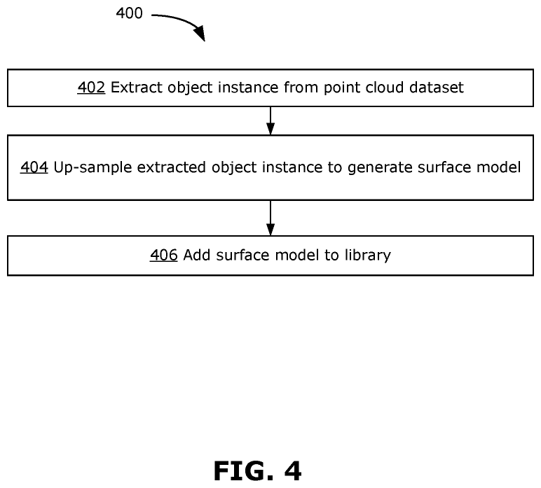

The memory 208 stores a dataset comprising a point cloud dataset 210. The point cloud dataset 210 includes a plurality of point cloud frames 212 and a plurality of labeled point cloud object instances 214, as described above with reference to FIG. 1. In some embodiments, some or all of the labeled point cloud object instances 214 are contained within and/or derived from the point cloud frames 212: for example, each point cloud frame 212 may include zero or more labeled point cloud object instances 214, as described above with reference to FIG. 1. In some embodiments, some or all of the labeled point cloud object instances 214 are stored separately from the point cloud frames 212, and each labeled point cloud object instance 214 may or may not originate from within one of the point cloud frames 212. The library generation module 330, as described below with reference to FIGS. 3-4, may perform operations to extract one or more labeled point cloud object instances 214 from one or more point cloud frames 212 in some embodiments.

The memory 208 may also store other data, information, rules, policies, and machine-executable instructions described herein, including a machine learned model 224, a surface model library 222 including one or more surface models, target point cloud frames 226, target surface models 228 (selected from the surface model library 222), transformed surface models 232, and augmented point cloud frames 230.

In some examples, the system 200 may also include one or more electronic storage units (not shown), such as a solid state drive, a hard disk drive, a magnetic disk drive and/or an optical disk drive. In some examples, one or more datasets and/or modules may be provided by an external memory (e.g., an external drive in wired or wireless communication with the system 200) or may be provided by a transitory or non-transitory computer-readable medium. Examples of non-transitory computer readable media include a RAM, a ROM, an erasable programmable ROM (EPROM), an electrically erasable programmable ROM (EEPROM), a flash memory, a CD-ROM, or other portable memory storage. The storage units and/or external memory may be used in conjunction with memory 208 to implement data storage, retrieval, and caching functions of the system 200.

The components of the system 200 may communicate with each other via a bus, for example. In some embodiments, the system 200 is a distributed system such as a cloud computing platform and may include multiple computing devices in communication with each other over a network, as well as optionally one or more additional components. The various operations described herein may be performed by different devices of a distributed system in some embodiments.

FIG. 3 illustrates the operation of an example library generation module 330, data augmentation module 340, and training module 234 executed by the processor 202 of the system 200. In the illustrated embodiment, the library generation module 330 includes several functional sub-modules or submodules (an instance extraction submodule 312 and an up-sampling submodule 314), and the data augmentation module 340 includes several functional sub-modules (a frame selection submodule 316, a transformation submodule 318, an instance injection submodule 320, and a surface model selection submodule 322). In other examples, one or more of the submodules 312, 314, 316, 318, 320, 322 may be combined, be split into multiple submodules, and/or have one or more of its functions or operations redistributed among other submodules. In some examples, the library generation module 330, data augmentation module 340, and/or training module 234 may include additional operations or sub-modules, or may omit one or more of the illustrated submodules 312, 314, 316, 318, 320, 322.

The operation of the various submodules of the library generation module 330 shown in FIG. 3 will now be described with reference to an example method 400 shown in FIG. 4.

FIG. 4 is a flowchart showing steps of an example method 400 for generating a surface model. As described, the steps of the method 400 are performed by the various submodules of the library generation module 330 shown in FIG. 3. However, it will be appreciated that the method 400 may be performed by any suitable information processing technology.

The method 400 begins at step 402. At 402, the instance extraction submodule 312 extracts a point cloud object instance from the point cloud dataset 210, thereby generating an extracted instance 306.

FIG. 1B shows a detailed view of an example labeled point cloud object instance 148 within a point cloud frame 212 generated by a LIDAR sensor (or other 3D sensor, as described above). The illustrated point cloud object instance 148 (e.g., one of the labeled point cloud object instances 214 selected from the point cloud dataset 210) consists of the second cluster of points 114 (i.e. the “bicyclist” point cloud object instance) from FIG. 1A, with the points 142 arranged along scan lines 144. The labeled point cloud object instance 148 thus includes a plurality of scan lines 144, each scan line 144 comprising a subset of the plurality of points 142 of the labeled point cloud object instance 148. The scan lines 144 correspond to points at which light emitted by a laser of the LIDAR sensor, moving along an azimuth direction in between taking readings, is reflected by an object, in this case a bicyclist, and detected by the LIDAR sensor. In the illustrated example, the azimuth direction defining the direction of the scan lines 144 is roughly horizontal (i.e. in the X-Y plane defined by the coordinate system 102 of the point cloud frame). The labeled point cloud object instance 148 includes a “bicyclist” object class label 134 and a bounding box 122 enclosing its points, as described above with reference to FIG. 1A.

In some embodiments, semantic information such as the object class label 134 and bounding box 122 may be generated by the instance extraction submodule 312 as part of the instance extraction step 402, using known techniques for point cloud object detection and/or point cloud frame segmentation. In other embodiments, the point cloud frames 212 of the point cloud dataset 210 already include labeled point cloud object instances 214 labeled and annotated with the semantic information.

The instance extraction submodule 312 obtains a point cloud frame (e.g., from the point cloud frames 212) and identifies points label with a given object class label 134 within the point cloud frame. If the frame is annotated using semantic segmentation such that multiple instances of an object are uniformly annotated with only an object class label and are not segmented into individual object instances, the instance extraction submodule 312 may cluster the points annotated with the object class label 134 to generate individual object instances of the object class indicated by the label 134 (e.g., using panoptic or instance segmentation, or using object recognition).

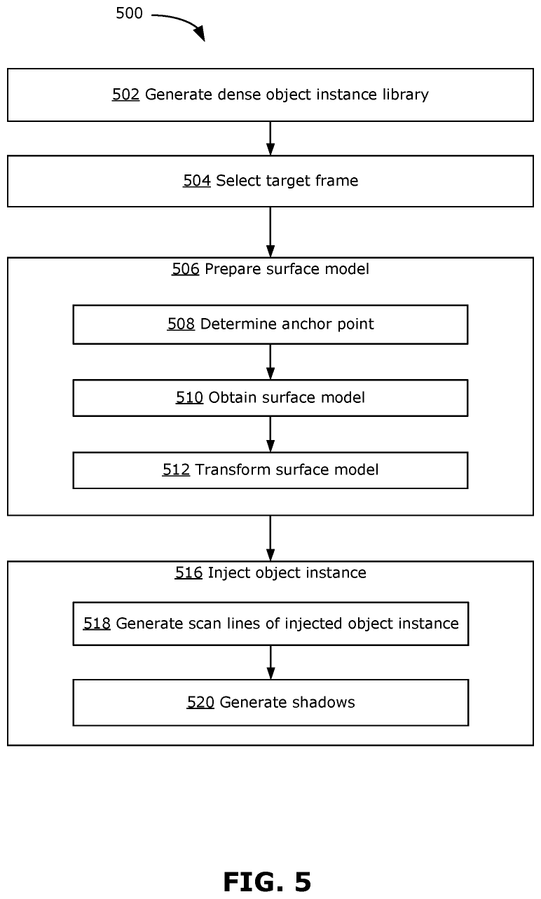

The labeled point cloud object instance 148, and the extracted instance 306 generated by the object extraction process, may include orientation information indicating an orientation of the labeled point cloud object instance 148 in relation to a sensor location. For example, the projection direction of the beam of light emitted by a laser of a LIDAR sensor used to generate the points 142 in the point cloud frame 212 may be recorded as part of the extracted instance 306, defined, e.g., as a directional vector using the coordinate system 102. Each point 142 may be recorded in a format that includes a set of (x, y, z) coordinates in the coordinate system 102. The intensity value of a point 142 may thus be understood as a function of the reflectivity of the object surface at the point of reflection of light from the object surface as well as the relationship between the directional vector defining the beam of light emitted by the LIDAR sensor used to generate the point and the spatial coordinates of the point 142, i.e. the orientation information of the extracted instance 306. The orientation information is thus used to represent a relationship between the directional vector of the beam of light and the surface normal of the object reflecting the light at that point in space. The orientation information may be used during the injection process (described below with reference to FIG. 5) to preserve the orientation of the injected point cloud object instance relative to the sensor location for the target point cloud frame (i.e. the point cloud frame into which the point cloud object instance is being injected) such that occlusions and intensity values are represented accurately.

The labeled point cloud object instance 148, and the extracted instance 306 generated by the object extraction process, may also include, for each point 144, point intensity information (e.g. an intensity value) and point location information (e.g. spatial (x, y, z) coordinates), as well as potentially other types of information, as described above with reference to FIG. 1A.

At 404, an up-sampling submodule 314 up-samples the extracted point cloud object instance 306 to generate a surface model, such as bicyclist surface model 152 shown in FIG. 1C.

FIG. 1C shows an example surface model 152 of a bicyclist generated by the up-sampling submodule 314 based on the extracted point cloud object instance 306 of the bicyclist object instance 148 shown in FIG. 1B. The up-sampling submodule 314 up-samples the point cloud cluster (i.e. second point cloud cluster 114, representing the bicyclist) of the extracted point cloud object instance 306 by using linear interpolation to increase the number of points in the cluster, both along each scan line 144 and between the scan lines 144. A point cloud object instance captured by a spinning scan LIDAR sensor usually has very different point density in the vertical direction (e.g., in an elevation direction roughly parallel to the Z axis) and horizontal direction (e.g., in an azimuth direction 157 roughly parallel to the X-Y plane). Conventional surface generation methods using polygon meshes to represent surfaces, for example greedy surface triangulation and Delaunay triangulation algorithms, yield a surface consisting of a polygon mesh with holes, which may result in scan lines missing points in an area corresponding to a hole and to points appearing in the shadow area of the surface during scanline and shadow generation (described below with reference to FIG. 5). In examples of the method and system described herein, in contrast, the point cloud object instance may be up-sampled directly by utilizing the character of the spinning scan LIDAR sensor. First, linear interpolation is performed on the points 142 of each scan line to increase the point density of each scan line 144 in the horizontal direction by adding new points 155 in between the existing points 142 of the scan line 144. Second, a set of points 142 are isolated using a thin sliding window 156 along the azimuth 157 (i.e. the window 156 isolates points 142 located in multiple scan lines 144 roughly aligned vertically with each other). Linear interpolation is used to increase the density of the points 142 in the vertical direction by adding new points 154 in between the scan lines 144. Thus, the point cloud object instance 148 is up-sampled by adding points 155 along the scan lines 144, and adding points 154 between pairs of the scan lines 144, using linear interpolation in both cases.

The added points 155, 154 use linear interpolation to assign both point location information and point intensity information to the added points 155, 154. This up-sampling may be performed on the azimuth-elevation plane, i.e. a plane defined by the sweep of the vertically-separated lasers along the azimuth direction 157 (e.g., in vertically separated arcs around the sensor location). The density of the surface model generated by the up-sampling submodule 314 can be controlled by defining an interval of interpolation, e.g. as a user-defined parameter of the library generation module 330. When the surface model is dense enough, shadow generation should not result in any points being left in the point cloud frame when the points should be occluded by the surface model, as described below with reference to FIG. 5.

The up-sampling submodule 314 includes other information in the surface model, such as the orientation information, point intensity information, and point location information of the point cloud object instance 148 used in generating the surface model. A reference point 158 may also be included in the surface model, indicating a single point in space with respect to which the surface model may be manipulated. In some embodiments, the reference point 158 is located on or near the ground at the bottom of the bounding box 122, in a central location within the horizontal dimensions of the bounding box 122: it may be computed as [xₘₑₐₙ, yₘₑₐₙ,zₘᵢₙ], i.e. with x and y values in the horizontal center of the X-Y rectangle of the bounding box, and with the lowest z value of the bounding box. Distance information may also be included, indicating a distance d from the sensor location of the original frame to the reference point 158 as projected onto the X-Y plane, e.g. computed as d=√xₘₑₐₙ²+yₘₑₐₙ².

At 406, the up-sampling submodule 314 adds the surface model to a surface model library 222. The surface models included in the surface model library 222 may be stored in association with (e.g., keyed or indexed by) their respective object class labels 134, such that all surface models for a given object class can be retrieved easily. The surface model library 222 may then be stored or distributed as needed, e.g. stored in the memory 208 of the system 200, stored in central location accessible by the system 200, and/or distributed on non-transitory storage media. The stored surface model library 222 may be accessible by the system 200 for use by training module 234.

The operation of the various submodules of the data augmentation module 340 shown in FIG. 3 will now be described with reference to an example method 500 shown in FIG. 5.

FIG. 5 is a flowchart showing steps of an example method 500 for injecting a surface model into a target point cloud frame. As described, the steps of the method 500 are performed by the various submodules submodule of the data augmentation module 340 shown in FIG. 3. However, it will be appreciated that the method 500 may be performed by any suitable information processing technology.

The method begins at step 502. At 502, a surface model library 222 is generated, for example by using the surface model generation method 400 of FIG. 4 performed by the library generation module 330. In some embodiments, step 502 may be omitted, and one or more pre-generated surface models may be obtained prior to performing the surface model injection method 500.

At 504, a target point cloud frame 226 is obtained by the data augmentation module 340. The target point cloud frame 226 may be selected from the point cloud dataset 210 by a frame selection submodule 316. In some examples, all point cloud frames 212 of the point cloud dataset 210 may be provided to the data augmentation module 340 for augmentation, whereas in other examples only a subset of the point cloud frames 212 are provided. One iteration of the method 500 is used to augment a single selected target point cloud frame 226.

At 506, a surface model is selected and prepared for injection into the target point cloud frame 226. An instance injection submodule 320 may receive the target point cloud frame 226 as well as, in some embodiments, control parameters used to control the selection and injection of the surface model into the target point cloud frame 226. An example format for the control parameters is:

{person, 2, [road, sidewalk, parking], [5%, 90%, 5%]}

indicating that two instances of the “person” object class will be injected into the target point cloud frame 226. Each “person” object instance may be injected into regions within the target point cloud frame 226 labeled with scene type labels 140 of scene type “road”, “sidewalk”, or “parking”, with probabilities of 5%, 90%, and 5%, respectively. In such an example, steps 506 and 516 of the method 500 would be repeated twice (to select and inject a surface model for each of the two point cloud object instances).

Step 506 includes sub-steps 508, 510, and 512. At sub-step 508, the instance injection submodule 320 determines an anchor point within the target point cloud frame 226, for example based on the scene type probability distribution indicated by the control parameters. The anchor point is used to position the injected point cloud object instance within the target point cloud frame 226, as described below with reference to sub-step 512.

In some embodiments, the anchor point may be generated in three steps. First, all possible anchor points are identified by using the scene type labels 140 and the object class labels of the target point cloud frame 226 to identify suitable regions and locations within regions where a point cloud object instance could realistically be injected into the target point cloud frame 226 (e.g., based on collision constraints with other objects in the target point cloud frame 226). Second, a probability p for each possible anchor point is computed based on the control parameters and any other constraints or factors. Third, the anchor point is selected based on the computed probabilities; for example, the potential anchor point with the highest computed probability may be selected as the anchor point.

The probability p of each anchor point candidate can be computed as P=Pₚₒₛ·P_{class}, wherein pₚₒₛ is a probability factor used to select an anchor point uniformly on the ground plane. For a spinning scanning LIDAR sensor, each point corresponds to a different area of the object reflecting a beam of light emitted by the laser at the point: the points that are close to the sensor location cover a smaller area than that of the points that are far from the sensor location. The anchor point is typically selected from points of the target point cloud frame 226 that are reflected by a ground surface. The selection probability of each point may be proportional to its covered area; otherwise, most of the anchor points will be generated near the sensor location. Thus, pₚₒₛ may be computed as

$${p}_{p o s} = {r}^{2} c tan θ = \frac{{( {x}^{2} + {y}^{2} )}^{3 / 2}}{\sqrt{{x}^{2} + {y}^{2} + {z}^{2}}}$$

The value of P_{class} may be determined by the control parameters, i.e. the probability of the anchor point being located within a region labelled with a given scene type label 140. Thus, the target point cloud frame 226 includes scene type information (e.g. scene type labels 140) indicating a scene type for one or more regions of the target point cloud frame 226, and this scene type information may be used to determine the value of P_{class} used by the computation of probability p to select an anchor point from the anchor point candidates. In some embodiments, the computation of probability p essentially determines that the surface model should be located within a given region based on the scene type of the region and the object class of the surface model. Once the anchor point has been selected of the anchor point candidates within the region, the anchor point is selected, and the corresponding location on the ground surface of the target point cloud frame 226 (referred to as the anchor location) within the region is used as the location for positioning and injecting the surface model, as described below at sub-step 512.

At sub-step 510, a surface model selection submodule 322 obtains a target surface model 228, for example by selecting, from the surface model library 222, a surface model associated with the object class identified in the control parameters described above. In some examples, the surface model library 222 includes surface models stored as dense point cloud object instances, such as those generated by method 400 described above. In some examples, the surface model library 222 includes surface models stored as computer assisted design (CAD) models. In some examples, the surface model library 222 includes surface models stored as complete dense point cloud object scans, i.e. dense point clouds representing objects scanned from multiple vantage points. Examples described herein will refer to the use of surface models consisting of dense point cloud object instances, such as those generated by method 400. However, it will be appreciated that the methods and systems described herein are also applicable to other surface model types, such as CAD models and complete dense point cloud object scans, even if the use of those surface model types may not exhibit all of the advantages that may be exhibited by the use of dense point cloud object instances generated by method 400.

Each surface model stored in the surface model library 222 may include object class information indicating an object class of the surface model. The surface model selection submodule 322 may retrieve a list of all surface models of a given object class in the library 222 that satisfy other constraints dictated by the control parameters and anchor point selection described above. For example, the surface model selection submodule 322 may impose a distance constraint, |r_{R}|≤|r_{A}|, requiring that the selected target surface model 228 have associated distance information indicating a distance d (also referred to as reference range |r_{R}|) less than or equal to the anchor point range |r_{A}|, indicating the distance from the sensor location to the anchor point in the target point cloud frame 226. Once a list is obtained or generated of all surface models in the library 222 satisfying the constraints (e.g., object class and spatial constraints), a surface model may be selected from the list using any suitable selection criteria, e.g. random selection.

At sub-step 512, the selected target surface model 228 is transformed by a transformation submodule 318, based on the anchor location, to generate a transformed surface model 232. An example of surface model transformation is illustrated in FIG. 1D.

FIG. 1D shows a top-down view of the transformation of a target surface model 228 to generate a transformed surface model 232. The target surface model 228 is shown as a bicycle surface model 152 with a bounding box 122, a “bicycle” object class label 134, a reference point 158, and orientation information shown as orientation angle 168 between an edge of the bounding box 122 and a reference direction shown by reference vector 172 extending from the sensor location 166 to the reference point 158. The reference vector 172 has a length equal to the distance d (i.e. reference range |r_{R}|).

The anchor point, determined at sub-step 508 above, is located at anchor location 160 within the target point cloud frame 226, which defines anchor point vector 170 pointing in an anchor point direction from the sensor location 166. The length of the anchor point vector 170 is anchor point range |r_{A}|.

The transformation submodule 318 computes a rotation angle θ between the reference direction (i.e. of reference vector 172) and the anchor point direction (i.e. of anchor point vector 170). The target surface model 228 is then rotated about an axis defined by the sensor location 166 of the target point cloud frame 226, while maintaining the orientation of the surface model in relation to the sensor location 166 (i.e. maintaining the same orientation angle 168), by rotation angle θ (i.e. between the surface model reference direction defined by reference vector 172 and the anchor point direction defined by anchor point vector 170).

The range or distance of the surface model is then adjusted using translation, i.e. linear movement. The transformation submodule 318 translates the surface model between a reference distance (i.e. reference range |r_{R}|, defined by the length of reference vector 172) and an anchor point distance (i.e. anchor point range |r_{A}|, defined by the length of anchor point vector 170).

In some examples, the surface model may then be scaled vertically and/or horizontally by some small amount relative to the anchor location 160 as appropriate, in order to introduce greater diversity into the object instances injected into the point cloud data, thereby potentially increasing the effectiveness of the data augmentation process for the purpose of training machine learned models.

The transformed surface model 232 is the end result of the rotation, translation, and scaling operations described above performed on the target surface model 228. In some examples, a collision test may be performed on the transformed surface model 232 by the instance injection submodule 320; if the transformed surface model 232 conflicts (e.g. collides or intersects) with other objects in the target point cloud frame 226, the method 400 may return to step 506 to determine a new anchor point and select a new surface model for transformation, and this process may be repeated until a suitable transformed surface model 232 is generated and positioned within the target frame 226.

At 516, the instance injection submodule 320 injects a point cloud object instance based on the surface model into the target point cloud frame 226. Step 516 includes sub-steps 518 and 520.

Prior to step 516, the instance injection submodule 320 has obtained the target point cloud frame 226 from the frame selection submodule 316 and the transformed surface model 232 from the transformation submodule 318, as described above. The transformed surface model 232 is positioned within the coordinate system 102 of the target point cloud frame 226. However, the transformed surface model 232 has no scan lines 144 on its surface, and it does not cast a shadow occluding other point within the target point cloud frame 226.

At sub-step 518, the instance injection submodule 320 generates scan lines 144 on the surface of the transformed surface model 232 to generate a point cloud object instance to be injected into the target point cloud frame 226. By adding the scan lines 144 of the transformed surface model 232 to the target point cloud frame 226, an augmented point cloud frame 230 is generated containing an injected point cloud object instance consisting of the points of the scan lines 144 mapped to the surface of the transformed surface model.

Each scan line 144 of the transformed surface model 232 is generated as a plurality of points 142 aligned with scan lines of the target point cloud frame 226. In some embodiments, the scan lines of the target point cloud frame 226 may be simulated by projecting the transformed surface model 232 onto a range image which corresponds to the resolution of the LIDAR sensor used to generate the target point cloud frame 226. Thus, for example, a range image may be conceived of as the set of all points in the target point cloud frame 226, with the spatial (x, y, z) coordinates of each point transformed into (azimuth, elevation, distance) coordinates, each point then being used to define a pixel of a two-dimensional pixel array in the (azimuth, elevation) plane. This two-dimensional pixel array is the range image. The azimuth coordinate may denote angular rotation about the Z axis of the sensor location, and the elevation coordinate may denote an angle of elevation or depression relative to the X-Y plane. By projecting the points of the transformed surface model 232 onto the range image of the target point cloud frame 226, the instance injection submodule 320 may identify those points of the transformed surface model 232 that fall within the area corresponding to the points of the beams of light of the scan performed by the LIDAR sensor used to generate the target point cloud frame 226. For each pixel of the range image containing at least one point of the projection of the transformed surface model 232, only the closest transformed surface model 232 point to the center of each pixel is retained, and the retained point is used to populate a scan line 144 on the surface of the transformed surface model 232, wherein the points of a given scan line 144 correspond to a row of pixels of the range image. The retained point is moved in the elevation direction to align with the elevation of the center of the range image pixel. This ensures that each point generated by pixels in that row all have the same elevation, resulting in an accurately elevated scan line 144.

In some embodiments, the range image is derived from the actual (azimuth, elevation) coordinates of transformed points of the target point cloud frame 226; however, other embodiments may generate the range image in a less computationally intensive way by obtaining the resolution of the LIDAR sensor used to generate the target point cloud frame 226 (which may be stored as information associated with the target point cloud frame 226 or may be derived from two or more points of the target point cloud frame 226) and generating a range image of the corresponding resolution without mapping pixels of the range image 1:1 to points of the target point cloud frame 226. In some embodiments, a range image based on the resolution may be aligned with one or more points of the frame after being generated.

In the augmented point cloud frame 230, the transformed surface model 232 is discarded, leaving behind only the scan lines 144 generated as described above. However, before discarding the transformed surface model 232, it may be used at sub-step 520 to generate shadows. The instance injection subsystem 320 determines shadows cast by the transformed surface model 232, identifies one or more occluded points of the target point cloud frame 226 located within the shadows, and removes the occluded points from the augmented point cloud frame 230. The range image is used to identify all pre-existing points of the target point cloud frame 226 falling within the area of each pixel. Each pixel containing at least one point of the scan lines 144 generated in sub-step 518 is considered to cast a shadow. All pre-existing points falling within the pixel (i.e. within the shadow cast by the pixel) are considered to be occluded points and are removed from the augmented point cloud frame 230.

The methods 400, 500 of FIGS. 4 and 5 may be used in conjunction to realize one or more advantages. First, the surface models obtained from an actual LIDAR-generated point cloud frame (i.e. a point cloud frame generated by a LIDAR sensor) in method 400 are usually half-side; the rotation of the surface model in method 500 ensures that the side with points always points toward the sensor location 166. Second, in some embodiments the anchor point range is constrained to be larger than the reference range by the transformation submodule 318 as described above (i.e. |r_{R}|≤|r_{A}|); thus, the density of the scan line points generated on the surface of the surface model will not increase in a way that magnifies any artifacts of the up-sampling process. (Although the density of the extracted object instance is increased by up-sampling, it does not increase the information contained in the original point cloud object instance). Other advantages of the combination of the methods 400, 500 will be apparent to a skilled observer.

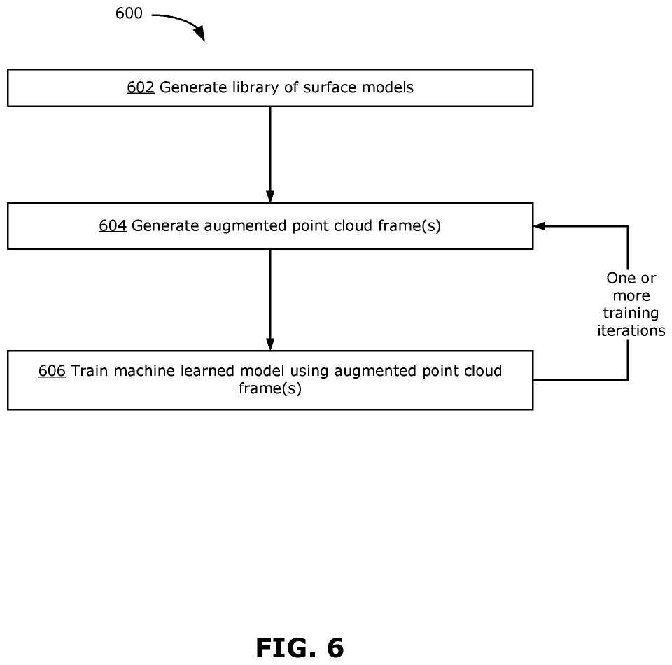

The library generation method 400 and data augmentation method 500 may be further combined with a machine learning process to train a machine learned model. The inter-operation of the library generation module 330, the data augmentation module 340, and the training module 234 shown in FIG. 3 will now be described with reference to an example method 600 shown in FIG. 6.

FIG. 6 is a flowchart showing steps of an example method 600 for augmenting point cloud dataset for use in training the machine learned model 224 for a prediction task. As described, the steps of the method 600 are performed by the various submodules of the library generation module 330, the data augmentation module 340, and the training module 234 shown in FIG. 3. However, it will be appreciated that the method 600 may be performed by any suitable information processing technology.

At 602, the library generation module 330 generates a library 222 of one or more surface models according to method 400.

At 604, the data augmentation module 340 generates one or more augmented point cloud frames 230 according to method 500.

At 606, the training module 234 trains a machine learned model 224 using the augmented point cloud frame(s) 230.

Steps 604 and 606 may be repeated one or more times to perform one or more training iterations. In some embodiments, a plurality of augmented point cloud frames 230 are generated before they are used to train the machine learned model 224.

The machine learned model 224 may be an artificial neural network or another model trained using machine learning techniques, such as supervised learning, to perform a prediction task on point cloud frames. The prediction task may be any prediction task for recognizing objects in the frame by object class or segmenting the frame by object class, including object recognition, semantic segmentation, instance segmentation, or panoptic segmentation. In some embodiments, the augmented point cloud frames 230 are added to the point cloud dataset 210, and the training module 234 trains the machine learned model 224 using the point cloud dataset 210 as a training dataset: i.e., the machine learned model 224 is trained, using supervised learning and the point cloud frames 212 and the augmented point cloud frames 230 included in the point cloud dataset 210, to perform a prediction task on point cloud frames 212, such as object recognition or segmentation on point cloud frames 212. The trained machine learned model 224 may be trained to perform object detection to predict object class labels, or may be trained to perform segmentation to predict instance labels and/or scene type labels to attach to zero or more subsets or clusters of points or regions within each point cloud frame 212, with the labels associated with each labelled point cloud object instance 214 or region in a given point cloud frame 212 used as ground truth labels for training. In other embodiments, the machine learned model 224 is trained using a different training point cloud dataset.

Although the present disclosure describes methods and processes with steps in a certain order, one or more steps of the methods and processes may be omitted or altered as appropriate. One or more steps may take place in an order other than that in which they are described, as appropriate.

Although the present disclosure is described, at least in part, in terms of methods, a person of ordinary skill in the art will understand that the present disclosure is also directed to the various components for performing at least some of the aspects and features of the described methods, be it by way of hardware components, software or any combination of the two. Accordingly, the technical solution of the present disclosure may be embodied in the form of a software product. A suitable software product may be stored in a pre-recorded storage device or other similar non-volatile or non-transitory computer readable medium, including DVDs, CD-ROMs, USB flash disk, a removable hard disk, or other storage media, for example. The software product includes instructions tangibly stored thereon that enable a processing device (e.g., a personal computer, a server, or a network device) to execute examples of the methods disclosed herein.

The present disclosure may be embodied in other specific forms without departing from the subject matter of the claims. The described example embodiments are to be considered in all respects as being only illustrative and not restrictive. Selected features from one or more of the above-described embodiments may be combined to create alternative embodiments not explicitly described, features suitable for such combinations being understood within the scope of this disclosure.

All values and sub-ranges within disclosed ranges are also disclosed. Also, although the systems, devices and processes disclosed and shown herein may comprise a specific number of elements/components, the systems, devices and assemblies could be modified to include additional or fewer of such elements/components. For example, although any of the elements/components disclosed may be referenced as being singular, the embodiments disclosed herein could be modified to include a plurality of such elements/components. The subject matter described herein intends to cover and embrace all suitable changes in technology.

1. A method comprising:
obtaining a point cloud object instance; and
up-sampling the point cloud object instance using interpolation to generate a surface model.

2. The method of claim 1, wherein:
the point cloud object instance comprises:
orientation information indicating an orientation of the point cloud object instance in relation to a sensor location; and
for each of a plurality of points in the point cloud object instance:
point intensity information; and
point location information; and
the surface model comprises the orientation information, point intensity information, and point location information of the point cloud object instance.

3. The method of claim 2, wherein:
the point cloud object instance comprises a plurality of scan lines, each scan line comprising a subset of the plurality of points; and
up-sampling the point cloud object instance comprises adding points along at least one scan line using linear interpolation.

4. The method of claim 3, wherein up-sampling the point cloud object instance further comprises adding points between at least one pair of scan lines of the plurality of scan lines using linear interpolation.

5. The method of claim 4, wherein adding a point using linear interpolation comprises:
assigning point location information to the added point based on linear interpolation of the point location information of two existing points; and
assigning point intensity information to the added point based on linear interpolation of the point intensity information of the two existing points.

6. A method comprising:
obtaining a target point cloud frame;
determining an anchor location within the target point cloud frame;
obtaining a surface model of an object;
transforming the surface model based on the anchor location to generate a transformed surface model;
generating scan lines of the transformed surface model, each scan line comprising a plurality of points aligned with scan lines of the target point cloud frame; and
adding the scan lines of the transformed surface model to the target point cloud frame to generate an augmented point cloud frame.

7. The method of claim 6, wherein the surface model comprises a dense point cloud object instance.

8. The method of claim 7, wherein obtaining the surface model comprises:
obtaining a point cloud object instance; and
up-sampling the point cloud object instance using interpolation to generate the surface model.

9. The method of claim 6, wherein the surface model comprises a computer assisted design (CAD) model.

10. The method of claim 6, wherein the surface model comprises a complete dense point cloud object scan.

11. The method of claim 6, further comprising:
determining shadows of the transformed surface model;
identifying one or more occluded points of the target point cloud frame located within the shadows; and
removing the occluded points from the augmented point cloud frame.

12. The method of claim 7, wherein generating the scan lines of the transformed surface model comprises:
generating a range image, comprising a two-dimensional pixel array wherein each pixel corresponds to a point of the target point cloud frame;
projecting the transformed surface model onto the range image; and
for each pixel of the range image, in response to determining that the pixel contains at least one point of the projection of the transformed surface model:
identifying a closest point of the projection of the transformed surface model to the center of the pixel; and
adding the closest point to the scan line.

13. The method of claim 6, wherein:
the surface model comprises object class information indicating an object class of the surface model;
the target point cloud frame comprises scene type information indicating a scene type of a region of the target point cloud frame; and
determining the anchor location comprises, in response to determining that the surface model should be located within the region based on the scene type of the region and the object class of the surface model, positioning the anchor location within the region.

14. The method of claim 6, wherein transforming the surface model based on the anchor location comprises:
rotating the surface model about an axis defined by a sensor location of the target point cloud frame, while maintaining an orientation of the surface model in relation to the sensor location, between a surface model reference direction and an anchor point direction; and
translating the surface model between a reference distance and an anchor point distance.

15. The method of claim 6, further comprising using the augmented point cloud frame to train a machine learned model.

16. A system for augmenting point cloud data, the system comprising:
a processor device; and
a memory storing:
a point cloud object instance;
a target point cloud frame; and
machine-executable instructions which, when executed by the processor device, cause the system to:
up-sample the point cloud object instance using interpolation to generate a surface model;
determine an anchor location within the target point cloud frame;
transform the surface model based on the anchor location to generate a transformed surface model;
generate scan lines of the transformed surface model, each scan line comprising a plurality of points aligned with scan lines of the target point cloud frame; and
add the scan lines of the transformed surface model to the target point cloud frame to generate an augmented point cloud frame.

17. A non-transitory processor-readable medium having stored thereon a surface model generated by the method of claim 1.

18. A non-transitory processor-readable medium having stored thereon an augmented point cloud frame generated by the method of claim 6.

19. A non-transitory processor-readable medium having machine-executable instructions stored thereon which, when executed by a processor device of a device, cause the device to perform the steps of the method of claim 1.

20. A non-transitory processor-readable medium having machine-executable instructions stored thereon which, when executed by a processor device of a device, cause the device to perform the steps of the method of claim 6.
